(19) United States
(12) Patent Application Publication
(10) Pub. No.: US 2020/0340755 A1
(43) Pub. Date: Oct. 29, 2020

(54) COOLING MODULE

(71) Applicant: SUNON ELECTRONICS (KUNSHAN) CO., LTD., Kunshan 215301 (CN)

(72) Inventors: Alex Horng, Kaohsiung (TW); Chin-Chun Liao, Kaohsiung (TW)

(21) Appl. No.: 16/732,535

(22) Filed: Jan. 2, 2020

(30) Foreign Application Priority Data
Apr. 29, 2019 (TW) 108114922

(51) Int. Cl. F28D 15/04; H05K 7/20

(52) U.S. Cl. CPC F28D 15/04; H05K 7/20309; H05K 7/20318; H05K 7/20336

(57) ABSTRACT

A cooling module includes at least one heat pipe and a fin unit. Each of the at least one heat pipe includes a condensing section between a first end and a second end of the heat pipe, a first vaporization section between the condensing section and the first end of the heat pipe, and a second vaporization section between the condensing section and the second end of the heat pipe. The condensing section intercommunicates with the first vaporization section and the second vaporization section. The fin unit is mounted to the condensing section of each of the at least one heat pipe.

### CROSS REFERENCE TO RELATED APPLICATION

The application claims the benefit of Taiwan application serial No. 108114922, filed on Apr. 29, 2019, and the entire contents of which are incorporated herein by reference.

### BACKGROUND OF THE INVENTION

### 1. Field of the Invention

The present invention generally relates to a cooling module and, more particularly, to a cooling module that permits the vapor and liquid to circulate in one or more heat pipes to thereby attain the required cooling effect.

### 2. Description of the Related Art

Excellent heat dissipation efficiency has been an important factor to ensure the performance of the electronic devices. Heat dissipation can be carried out in various ways. For example, a fan can be provided to facilitate the air circulation, or one or more pipes can be provided to permit circulation of the vapor and liquid for cooling purposes. A conventional cooling module includes a plurality of heat pipes, each containing cooling liquid. Each heat pipe is in an “L” shape and includes a vaporization end and a condensing end. The vaporization ends of the heat pipes are connected to a heat-conductive board, and the condensing ends of the heat pipes are connected to a fin unit. The condensing ends of the heat pipes are independent of each other and are not in intercommunication.

Since the condensing ends of the heat pipes are independent of each other and are not in intercommunication, the cooling liquid cannot circulate in the area covered by the fin unit. This not only makes it difficult to improve the heat dissipation efficiency, but also requires the use of more heat pipes. As a result, it is required to perform more cutting operations and to seal two ends of each heat pipe, making it difficult to reduce the manufacturing cost.

In light of this, it is necessary to improve the conventional cooling module.

### SUMMARY OF THE INVENTION

It is therefore the objective of this invention to provide a cooling module which forms a vaporization section at each of two ends of the heat pipe, as well as a condensing section between the two ends of the heat pipe which allows for circulation of the cooling liquid. In this arrangement, the entire condensing section can be used to dissipate the heat of the cooling liquid, thereby improving the cooling efficiency and reducing the manufacturing cost.

It is another objective of this invention to provide a cooling module which has a more stable temperature throughout the heat pipe.

It is a further objective of this invention to provide a cooling module with convenient assembly.

As used herein, the term “one” or “an” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

As used herein, the term “coupling”, “join”, “assembly” or the like is used to include separation of connected members without destroying the members after connection or inseparable connection of the members after connection. A person having ordinary skill in the art would be able to select the type of connection according to desired demands in the material or assembly of the members to be connected.

In an aspect, a cooling module includes at least one heat pipe and a fin unit. Each of the at least one heat pipe includes a condensing section between a first end and a second end of the heat pipe, a first vaporization section between the condensing section and the first end of the heat pipe, and a second vaporization section between the condensing section and the second end of the heat pipe. The condensing section intercommunicates with the first vaporization section and the second vaporization section. The fin unit is mounted to the condensing section of each of the at least one heat pipe.

Based on this, each of the at least one heat pipe of the cooling module of the invention forms two vaporization sections respectively at two ends of the heat pipe, as well as a condensing section between the two ends of the heat pipe. Thus, the working fluid can dissipate its heat in the entire condensing section to improve the cooling efficiency and reduce the manufacturing cost.

In a form shown, the cooling module further includes a heat conducting board in thermal connection to the first vaporization section and the second vaporization section of each of the at least one heat pipe. Thus, the heat conducting board can absorb the heat of the heat source, thereby improving the cooling efficiency of the cooling module.

In the form shown, the condensing section is in a form of a flat pipe having two opposite flat surfaces, and the fin unit abuts at least one of the two flat surfaces. Thus, the contact area between the condensing section and the fin unit increases, thereby improving the cooling efficiency of the cooling module.

In the form shown, the cooling module further includes a connector connected to the first end and the second end of each of the at least one heat pipe, and an interior of the connector intercommunicates with the first vaporization section and the second vaporization section of each of the at least one heat pipe. Based on this, the working fluid can circulate in the entire heat pipe, thereby improving the cooling efficiency of the cooling module.

In the form shown, the condensing section forms at least one U-shaped portion located completely within an extent of the fin unit. Thus, the fin unit can cover the entire condensing section to thereby improve the cooling efficiency of the cooling module.

In the form shown, the condensing section forms at least one U-shaped portion partially protruding beyond the fin unit. Thus, a smaller fun unit can be used to connect to the condensing section, thereby reducing the material cost of the cooling module.

In the form shown, the at least one heat pipe includes a single heat pipe delimiting a T-shape area, and a U-shaped portion forms at each of two sides of the T-shape area. Thus, the structure is simple and the manufacturing is convenient, thereby reducing the manufacturing cost.

In the form shown, the at least one heat pipe includes two heat pipes. Each of the two heat pipes delimits a boot-like area and forms the condensing section having a heel and a toe. The condensing sections of the two heat pipes are on a same plane. The heels of the condensing sections of the two heat pipes are adjacent to each other. Thus, two condensing sections can be formed, thereby improving the cooling efficiency.

In the form shown, the at least one heat pipe includes a plurality of heat pipes, and at least one of the plurality of heat pipes has an outer diameter different from an outer diameter of any other of the plurality of heat pipes. Thus, the heat pipes can be used in different electronic devices according to the requirement, thereby providing a wide use of the cooling module.

In the form shown, the at least one heat pipe includes a plurality of heat pipes, each of the plurality of heat pipes delimits a T-shaped area or a boot-like area, and the condensing sections of the plurality of heat pipes are on at least two different planes. Thus, the shape of the plurality of heat pipes can be adjusted according to different mechanical designs, thereby improving convenience in use of the cooling module.

In the form shown, the first vaporization sections and the second vaporization sections of the plurality of heat pipes are on a same plane. Thus, the structure is simple and the assembly is convenient, thereby improving convenience in assembly.

In the form shown, the at least one heat pipe includes two heat pipes. The fin unit includes a bottom fin, a top fin, and an intermediate fin connected to the bottom fin and the top fin. The bottom fin is connected to one of the condensing sections of the two heat pipes. The top fin is connected to another of the condensing sections of the two heat pipes. The intermediate fin is connected to the condensing sections of the two heat pipes. Thus, the cooling function can be attained through the use of the three fins, thereby improving the cooling efficiency of the cooling module.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is an exploded, perspective view of a cooling module according to a first embodiment of the invention.

FIG. 2 is a top view of the assembled cooling module of the first embodiment of the invention.

FIG. 3 is a top view of an assembled cooling module according to a second embodiment of the invention.

FIG. 4 is an exploded, perspective view of a cooling module according to a third embodiment of the invention.

FIG. 5 is a top view of the assembled cooling module of the third embodiment showing the points of temperature measurement.

FIG. 6 shows the temperature curves of the conventional cooling module and the disclosed cooling module of the third embodiment.

FIG. 7 is an exploded, perspective view of a cooling module according to a fourth embodiment of the invention.

FIG. 8 is an exploded, perspective view of a cooling module according to a fifth embodiment of the invention.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

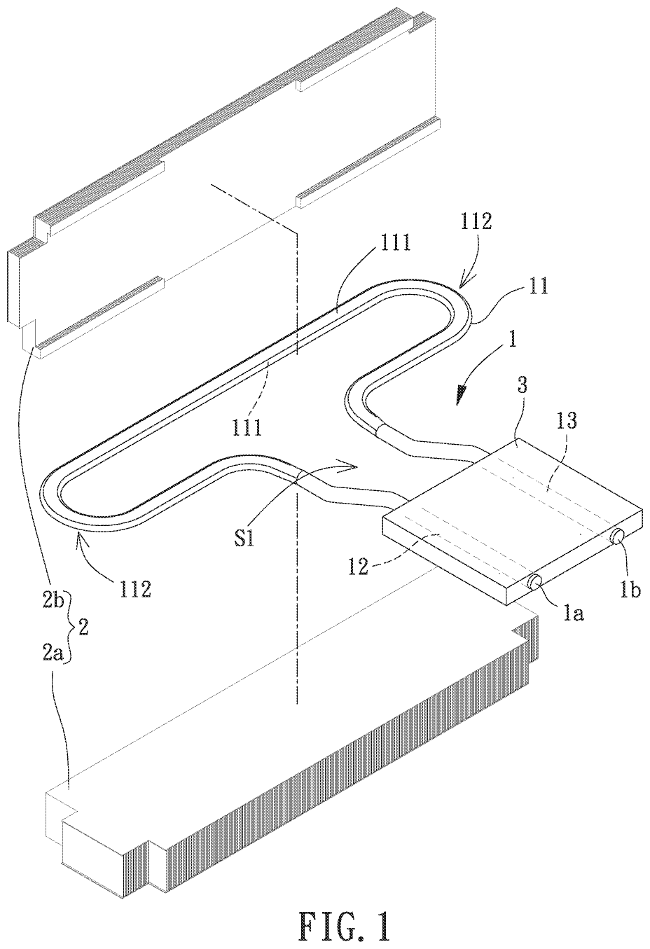

FIG. 1 shows a cooling module according to a first embodiment of the present invention. The cooling module includes at least one heat pipe 1 and a fin unit 2 that is directly or indirectly coupled with the at least one heat pipe 1.

The at least one heat pipe 1 can be made of a heat-conductive material and preferably forms a regular or irregular capillary structure on the inner periphery thereof. The at least one heat pipe 1 is filled with a working fluid and includes only one heat pipe 1 in this embodiment. The heat pipe 1 has a closed first end 1a and a closed second end 1b, with a condensing section 11 forming between the first end 1a and the second end 1b. The shape of the condensing section 11 is not limited in the present invention. In this embodiment, the condensing section 11 is flattened by punching or roll forming, shaping the condensing section 11 as a flat pipe with two opposite flat surfaces 111. It is particularly noted that the length of the heat pipe 1 is preferably larger than or equal to 19 times of the outer diameter of the heat pipe 1. In this arrangement, the heat pipe 1 has a sufficient length for bending purpose. The shape into which the heat pipe 1 is bent is not limited in the present invention, which can be an inversed “U” shape or an “M” shape. In this embodiment, the heat pipe 1 is bent to delimit a T-shape area S1, forming a U-shaped portion 112 at each side of the condensing section 11.

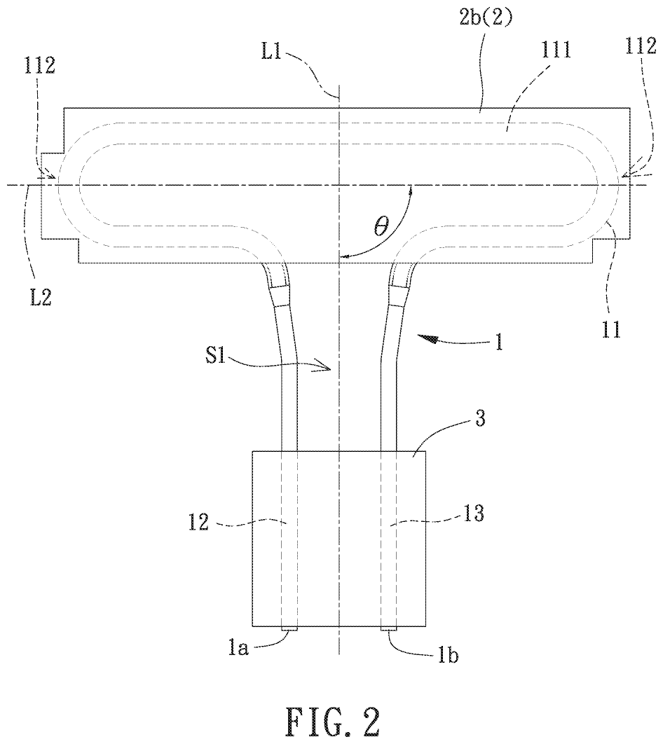

Specifically, referring to FIGS. 1 and 2, the heat pipe 1 includes a first vaporization section 12 between the first end 1a and the condensing section 11 of the heat pipe 1, and a second vaporization section 13 between the second end 1b and the condensing section 11 of the heat pipe 1. The first vaporization section 12 and the second vaporization section 13 are intercommunicating with the condensing section 11 of the heat pipe 1. In other words, for a single heat pipe 1, the first vaporization section 12 and the second vaporization section 13 are respectively located at the head and tail of the heat pipe 1. The condensing section 11 is located at the intermedium section of the heat pipe 1. The first vaporization section 12 and the second vaporization section 13 may be disposed at a heat source (not shown). Besides, a vaporization axis L1 is defined to extend in parallel to the first vaporization section 12 and the second vaporization section 13. The two U-shaped portions 112 are opposite to each other in an extending direction of a condensing axis L2. The condensing axis L2 is at an angle θ to the vaporization axis L1. The angle θ is between 60-120 degrees.

The fin unit 2 is mounted to the condensing section 11 of the heat pipe 1. The fin unit 2 can be made of a metal material with excellent heat conductivity. Before the fin unit 2 is mounted to the condensing section 11, the fin unit 2 can be integrally formed. In this embodiment, the fin unit 2 includes a bottom fin 2a below the condensing section 11 and a top fin 2b on the condensing section 11. The bottom fin 2a and the top fin 2b can respectively abut the flat surfaces 111 of the condensing section 11 to increase the contact areas between the condensing section 11 and the fin unit 2. Furthermore, in this embodiment, the two U-shaped portions 112 of the condensing section 11 of the heat pipe 1 can be located completely within the range of the fin unit 2. Besides, a cooling fan (not shown) can be used to draw the heat of the fin unit 2, thus expelling the heat of the fin unit 2. The cooling fan can also blow air toward the fin unit 2 to reduce the temperature of the fin unit 2. As such, the heat of the fin unit 2 can be expelled to reduce the temperature of the heat pipe 1.

The cooling module according to the present invention can further include a heat conducting board 3 which is made of a metal material with excellent heat conductivity. Thus, the heat conducting board 3 can be thermally connected to the first vaporization section 12 and the second vaporization section 13. The manner in which the heat conducting board 3 is connected to the first vaporization section 12 and the second vaporization section 13 is not limited. In this embodiment, the first vaporization section 12 and the second vaporization section 13 extend into the heat conducting board 3 and are welded to the heat conducting board 3 through solder to establish the thermal connection. As such, the first end 1a and the second end 1b of the heat pipe 1 can extend out of or remain in the heat conducting board 3.

Referring to FIG. 2, based on the above structure, during the use of the cooling module according to the invention, the heat conducting board 3 can be mounted to a heat source such as an electronic device (not shown). The heat conducting board 3 can absorb the heat to vaporize the working fluid in the first vaporization section 12 and the second vaporization section 13 to produce vapor. The vapor flows into the condensing section 11 and the heat of the vapor is expelled through the fin unit 2. Therefore, the vapor cools down and turns back into liquid in the condensing section 11. At the same time, the fin unit 2 keeps expelling the heat of the heat source to thereby reduce its temperature. Since the condensing section 11 is between the first vaporization section 12 and the second vaporization section 13, the working fluid can have a path to dissipate its heat along the path, improving the cooling efficiency of the cooling module.

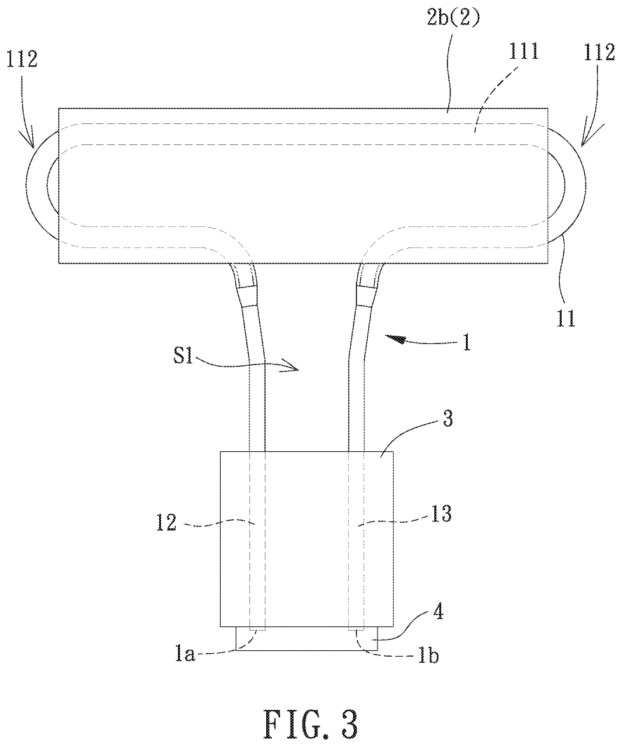

FIG. 3 shows a cooling module according to a second embodiment of the invention. The cooling module in the embodiment can further include a connector 4. The inner periphery of the connector 4 preferably forms a regular or irregular capillary structure. Specifically, the first end 1a and the second end 1b of the heat pipe 1 can be cut open such that the first end 1a and the second end 1b of the heat pipe 1 can be connected to the connector 4. In this regard, the first end 1a and the second end 1b of the heat pipe 1 can intercommunicate with the interior of the connector 4 to permit the working fluid to circulate in the heat pipe 1, advantageously improving the cooling efficiency. Besides, when the cooling effect is excellent such that it appears to be unnecessary to use that many fins, a smaller fin unit 2 can be used to connect to the condensing section 11. In this arrangement, the U-shaped portion 112 can partially protrude beyond the fin unit 2. As a result, the material cost of the fin unit 2 can be reduced.

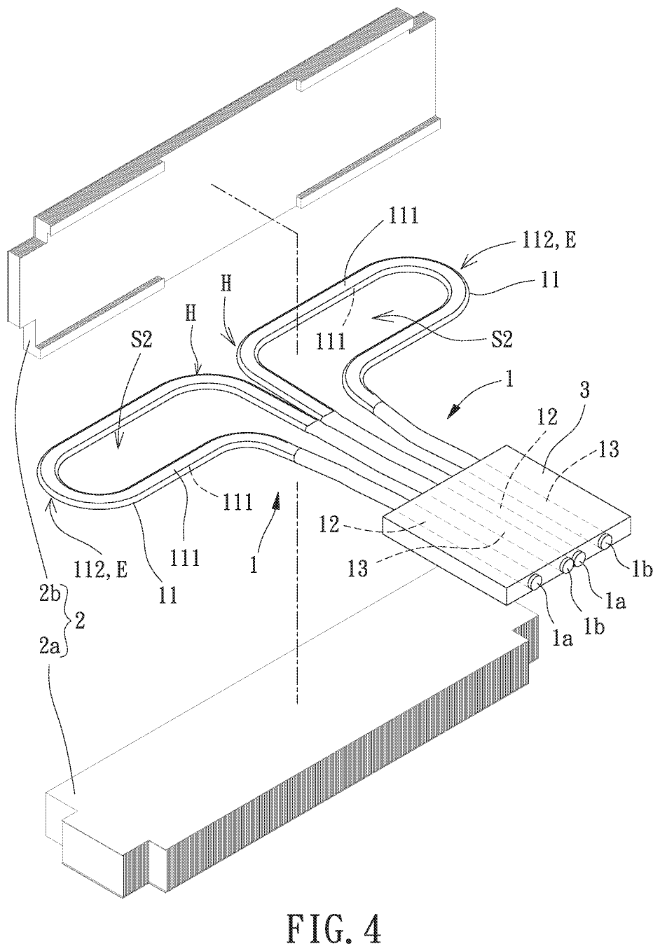

FIG. 4 shows a cooling module according to a third embodiment of the invention. The number of the at least one heat pipe 1 is two. Each of the two heat pipes 1 delimits a boot-like area S2. Each of the two heat pipes 1 forms a condensing section 11, such that the cooling module in this embodiment has two condensing sections 11. Each of the two condensing sections 11 includes a heel H and a toe E. The toe E is the aforementioned U-shaped portion 112. The two condensing sections 11 can be stacked together or disposed side by side. In this embodiment, the two condensing sections 11 are on the same plane, with the heels H thereof being adjacent to each other. The first vaporization sections 12 and the second vaporization sections 13 of the two heat pipes 1 are alternately disposed side by side in the heat conducting board 3. Through the arrangement of the two heat pipes 1, the cooing efficiency can be further enhanced.

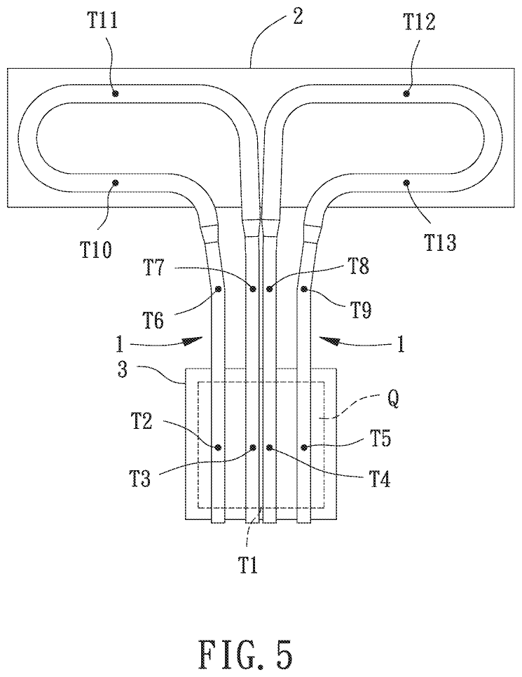

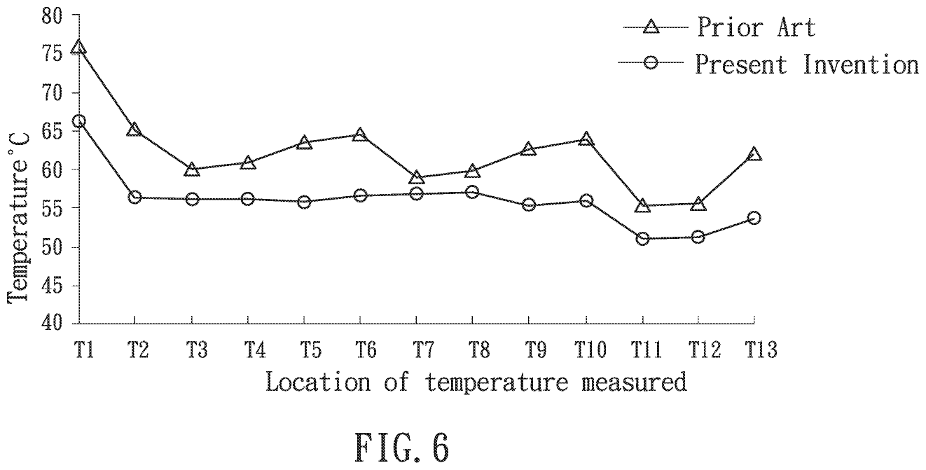

For experimental purpose, FIG. 5 shows an arrangement where the cooling module of the third embodiment is used to dissipate the heat of a heat source Q. The temperatures of various points of the two heat pipes 1 are measured, as labelled with T2, T3, T4, T5, T6, T7, T8, T9, T10, T11, T12 and T13. The temperature of the heat source Q is measured at point T1. The measurement point T1 can be located between the heat conducting board 3 and the heat source Q. Then, the cooling module of the third embodiment is replaced with the conventional cooling module to measure the temperatures of the above points under the same arrangement. Finally, two temperature curves are obtained as shown in FIG. 6.

It can be recognized from FIG. 6 that the temperatures of the above points measured with the cooling module of the invention are lower than the temperatures measured with the conventional cooling module. Thus, the cooling module of the invention can effectively improve the cooling effect. Besides, it is noted that, as compared with the conventional type of the heat pipe of the cooling module where the above points have larger temperature differences, the measured points of the proposed type of the heat pipes of the cooling module have more stable temperature. As a result, the phase transition of the working fluid is more stable. It is therefore proven that the cooling module of the invention can improve the cooling efficiency.

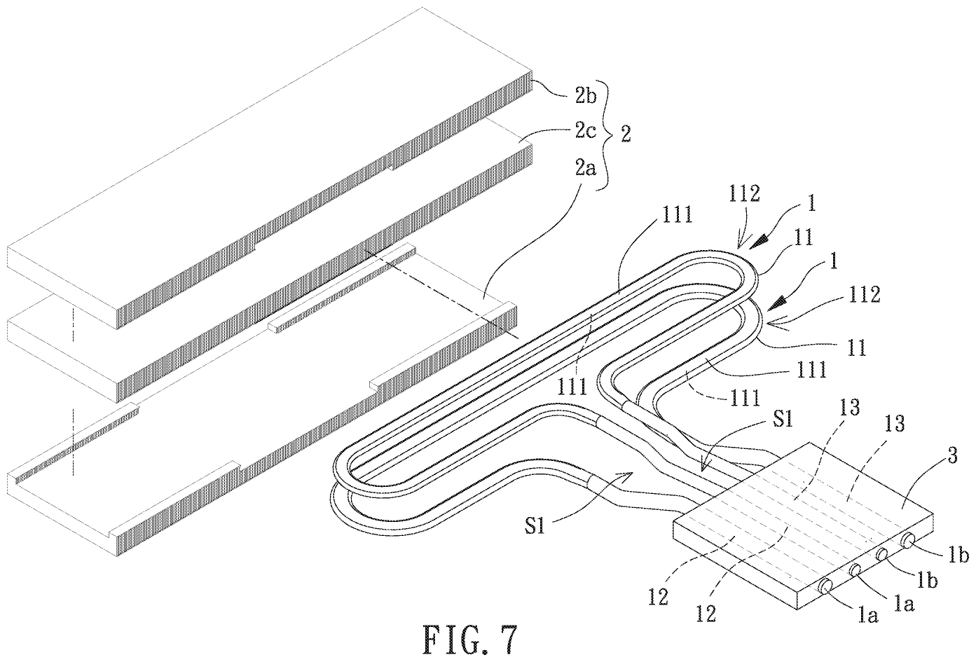

FIG. 7 shows a cooling module according to a fourth embodiment of the invention. The quantity of the at least one heat pipe 1 is plural. At least one of the heat pipes 1 has a different outer diameter from other heat pipe(s) 1. In this embodiment, two heat pipes 1 are used for explanation purpose. From FIG. 7, each heat pipe 1 delimits a T-shaped area S1. The condensing sections 11 of the heat pipes 1 are on different planes while the first vaporization sections 12 and the second vaporization sections 13 of the heat pipes 1 are on the same plane. In this regard, the fin unit 2 further includes an intermediate fin 2c between the bottom fin 2a and the top fin 2b. The bottom fin 2a is connected to the condensing section 11 of one of the heat pipes 1, the top fin 2b is connected to the condensing section 11 of the other of the heat pipes 1, and the intermediate fin 2c is connected to both the condensing sections 11 of the heat pipes 1. In this arrangement, the cooling efficiency is further improved.

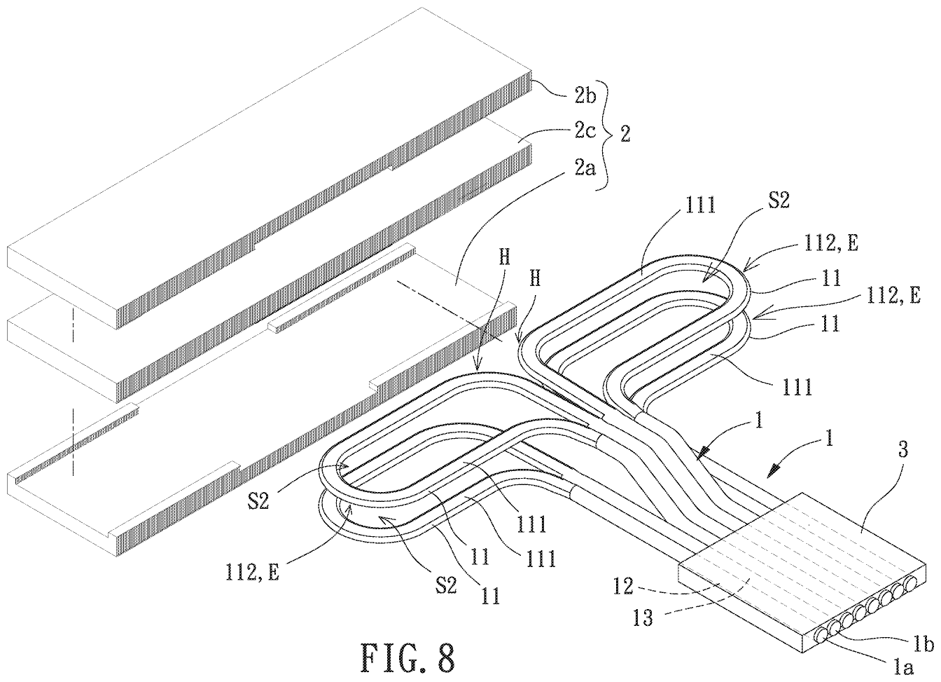

FIG. 8 shows a cooling module according to a fifth embodiment of the invention. The quantity of the at least one heat pipe 1 is four. Each of the four heat pipes 1 delimits a boot-like area S2. Each of the four heat pipes 1 forms a condensing section 11, such that the cooling module in this embodiment has four condensing sections 11. Each of the four condensing sections 11 includes a heel H and a toe E. The toe E is the aforementioned U-shaped portion 112. The four condensing sections 11 can be stacked together or disposed side by side. In this embodiment, the four condensing sections 11 are in two pairs, with each pair of the condensing sections 11 being on the same plane where the heels H of the two condensing sections 11 are adjacent to each other. In this regard, the four condensing sections 11 are at two different levels, and the first vaporization sections 12 and the second vaporization sections 13 of the four heat pipes 1 are alternately disposed side by side in the heat conducting board 3. Through the arrangement of the four heat pipes 1, the cooling efficiency can be further enhanced.

In summary, each of the at least one heat pipe of the cooling module of the invention forms two vaporization sections respectively at two ends of the heat pipe, as well as a condensing section between the two ends of the heat pipe. Thus, the working fluid can have a path to dissipate its heat along the path, thus improving the cooling efficiency and reducing the manufacturing cost.

Although the invention has been described in detail with reference to its presently preferable embodiments, it will be understood by one of ordinary skill in the art that various modifications can be made without departing from the spirit and the scope of the invention, as set forth in the appended claims

What is claimed is:

1. A cooling module comprising:
at least one heat pipe, wherein each of the at least one heat pipe includes a condensing section between a first end and a second end of the heat pipe, a first vaporization section between the condensing section and the first end of the heat pipe, and a second vaporization section between the condensing section and the second end of the heat pipe, and wherein the condensing section intercommunicates with the first vaporization section and the second vaporization section; and
a fin unit mounted to the condensing section of each of the at least one heat pipe.

2. The cooling module as claimed in claim 1, further comprising a heat conducting board in thermal connection to the first vaporization section and the second vaporization section of each of the at least one heat pipe.

3. The cooling module as claimed in claim 1, wherein the condensing section is in a form of a flat pipe having two opposite flat surfaces, and wherein the fin unit abuts at least one of the two flat surfaces.

4. The cooling module as claimed in claim 1, further comprising a connector connected to the first end and the second end of each of the at least one heat pipe, and wherein an interior of the connector intercommunicates with the first vaporization section and the second vaporization section of each of the at least one heat pipe.

5. The cooling module as claimed in claim 1, wherein the condensing section forms at least one U-shaped portion located completely within an extent of the fin unit.

6. The cooling module as claimed in claim 1, wherein the condensing section forms at least one U-shaped portion partially protruding beyond the fin unit.

7. The cooling module as claimed in claim 1, wherein the at least one heat pipe includes a single heat pipe delimiting a T-shape area, and wherein a U-shaped portion forms at each of two sides of the condensing section.

8. The cooling module as claimed in claim 1, wherein the at least one heat pipe includes two heat pipes, wherein each of the two heat pipes delimits a boot-like area and forms the condensing section having a heel and a toe, wherein the condensing sections of the two heat pipes are on a same plane, and wherein the heels of the condensing sections of the two heat pipes are adjacent to each other.

9. The cooling module as claimed in claim 1, wherein the at least one heat pipe includes a plurality of heat pipes, and wherein at least one of the plurality of heat pipes has an outer diameter different from an outer diameter of any other of the plurality of heat pipes.

10. The cooling module as claimed in claim 1, wherein the at least one heat pipe includes a plurality of heat pipes, wherein each of the plurality of heat pipes delimits a T-shaped area or a boot-like area, and wherein the condensing sections of the plurality of heat pipes are on at least two different planes.

11. The cooling module as claimed in claim 10, wherein the first vaporization sections and the second vaporization sections of the plurality of heat pipes are on a same plane.

12. The cooling module as claimed in claim 10, wherein the at least one heat pipe includes two heat pipes, wherein the fin unit includes a bottom fin, a top fin, and an intermediate fin connected to the bottom fin and the top fin, wherein the bottom fin is connected to one of the condensing sections of the two heat pipes, wherein the top fin is connected to another of the condensing sections of the two heat pipes, and wherein the intermediate fin is connected to the condensing sections of the two heat pipes.

13. The cooling module as claimed in claim 1, wherein a length of one of the at least one heat pipe is larger than or equal to 19 times of an outer diameter of the heat pipe.
